(19) United States
(12) Patent Application Publication
(10) Pub. No.: US 2022/0005908 A1
(43) Pub. Date: Jan. 6, 2022

(54) DISPLAY PANEL

(71) Applicant: WUHAN CHINA STAR OPTOELECTRONICS SEMICONDUCTOR DISPLAY TECHNOLOGY CO., LTD, Wuhan, Hubei (CN)

(72) Inventors: Xing MING, Wuhan, Hubei (CN); Weiqi ZHANG, Wuhan, Hubei (CN)

(21) Appl. No.: 16/641,345

(22) PCT Filed: Jan. 8, 2020
(86) PCT No.: PCT/CN2020/070923

§ 371 Date: Feb. 24, 2020

(30) Foreign Application Priority Data
Aug. 9, 2019 (CN) 201910734220.X

(51) Int. Cl. H01L 27/32; H01L 51/00; H01L 51/52

(52) U.S. Cl. CPC H01L 27/3276; H01L 51/5253; H01L 51/0097; H01L 27/3246

(57) ABSTRACT

A display panel comprising a front surface area and a back surface area is provided. The back surface area is disposed on a back side of the front surface area through a bending area having a bending structure. The display panel comprises a substrate layer, a barrier layer, a first electrode layer, a first organic layer, and a second electrode layer. In the bending area, it can make the second electrode layer cause a less bending deformation by disposing openings respectively in the barrier layer, the first electrode layer, and the first organic layer and disposing the second electrode layer along a bevel of the opening of the first organic layer to the substrate layer, thereby reducing a bending stress of the second electrode layer in the bending area, reducing the risk of breaking the second electrode layer, and improving quality of display panels and the yield of the process.

### CROSS REFERENCE TO RELATED APPLICATIONS

The present application claims priority of the Chinese patent application No. CN201910734220.X filed on Aug. 9, 2019 with the National Intellectual Property Administration, titled “Display panel”, which is incorporated by reference in the present application in its entirety.

### FIELD OF INVENTION

The present disclosure relates to the field of display technologies, and more particularly, to a display panel.

### BACKGROUND OF INVENTION

Compared to liquid crystal displays (LCDs), the biggest advantage of organic light-emitting diode (OLED) displays is that they can be manufactured on a flexible substrate. Because organic light-emitting materials of OLEDs have bending resistance, OLED display panels can be bent and folded. If a part of a lower border of an OLED display panel can be folded to a back surface of the display panel, size of the lower border of the OLED display panel can be further reduced, thereby achieving a very narrow border effect or a rimless effect.

In narrow border designs of OLED display panels, a part of a border which is folded to the back surface would make a control chip connected to elements of a front surface of the display panel by interior metal wirings thereof. In the process of folding a part of a border, metal wirings would be bent around a bending center of a bottom layer of the part of the border. However, in current technology, since there is a greater thickness of film layers between the metal wirings and the bottom layer of the part of the border, a greater amount of deformation would be generated when the metal wirings are bent around the bending center, thereby increasing a risk of breaking the metal wirings.

Technical problem: in the folding process of display panels, metal wirings in a bending area would generate a greater amount of deformation that causes the metal wirings to be broken, making the display panels lose display function.

### SUMMARY OF INVENTION

To solve the above technical problem, solutions of the present disclosure are as follows:

The present disclosure provides a display panel. The display panel comprises a display area, a back surface area, and a bending area connected to a front surface area and the back surface area;

wherein the bending area is a bending structure, and the back surface area is disposed on a back side of the front surface area through the bending area.

the display panel comprises:

a substrate layer;

a barrier layer disposed on the substrate layer;

a first electrode layer disposed on the barrier layer;

a first organic layer disposed on the first electrode layer; and

a second electrode layer disposed on the first organic layer;

wherein in the bending area, the barrier layer has a first opening, the first electrode layer has a second opening, the first organic layer has a third opening and covers an endface of the first opening and an endface of the second opening, and an endface of the third opening is a ramp structure.

In the display panel of the present disclosure, wherein in the bending area, the endface of the third opening extends to the substrate layer correspondingly.

In the display panel of the present disclosure, wherein a width of the second opening is greater than a width of the first opening.

In the display panel of the present disclosure, wherein in the bending area, an included angle between the endface of the third opening and the substrate layer is less than 40 degrees.

In the display panel of the present disclosure, wherein in the bending area, two ends of the third opening are not in contact with each other.

In the display panel of the present disclosure, wherein in the bending area, a part of the second electrode layer is disposed on the substrate layer.

In the display panel of the present disclosure, wherein in the bending area, the second electrode layer is disposed along the endface of the third opening and a surface of the substrate layer toward the barrier layer.

In the display panel of the present disclosure, wherein in the bending area, at least a part of the second electrode layer has an arc structure.

The display panel of the present disclosure further comprises a second organic layer disposed on the second electrode layer.

In the display panel of the present disclosure, wherein in the bending area, at least a part of the second organic layer has an arc structure.

The display panel of the present disclosure further comprises a pixel definition layer disposed on the second organic layer.

In the display panel of the present disclosure, wherein in the bending area, at least a part of the pixel definition layer has an arc structure.

In the display panel of the present disclosure, wherein the pixel definition layer comprises red, green, and blue sub-pixel units.

In the display panel of the present disclosure, wherein the substrate layer is a flexible substrate.

In the display panel of the present disclosure, wherein the substrate layer is made of polyimide.

In the display panel of the present disclosure, wherein the first organic layer is provided with a through hole filled with a conductive material, and the first electrode layer is electrically connected to the second electrode layer by the conductive material in the through hole.

In the display panel of the present disclosure, wherein the first electrode layer and the second electrode layer comprise a plurality of wirings and a plurality of electrodes, and at least a part of the wirings and/or electrodes in the first electrode layer is electrically connected to the wirings and/or electrodes in the second electrode layer by the conductive material in the through hole.

In the display panel of the present disclosure, wherein the barrier layer consists of an inorganic layer and a third organic layer, the inorganic layer is disposed on the substrate layer, and the third organic layer is disposed on the inorganic layer.

Beneficial effect: the display panel provided by the present disclosure comprises a front surface area and a back surface area. The back surface area is disposed on a back side of the front surface area through a bending area having a bending structure. In the bending area, the present disclosure can make the second electrode layer cause a less bending deformation by disposing openings respectively in the barrier layer, the first electrode layer, and the first organic layer, and disposing the second electrode layer along a bevel of the opening of the first organic layer to the substrate layer, thereby reducing a bending stress of the second electrode layer in the bending area, reducing the risk of breaking the second electrode layer, and improving quality of display panels and the yield of the process.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which figures those skilled in the art can derive further figures without making any inventive efforts.

FIG. 1 is a schematic structural diagram of a display panel (before a bending area is bent) according to an embodiment of the present disclosure.

FIG. 2 is a cross-sectional diagram of the display panel (before a bending area is bent) shown in FIG. 1 along an A-A′ direction.

FIG. 3 is a cross-sectional diagram of the display panel shown in FIG. 1 (after the bending area is bent) along the A-A′ direction.

### DETAILED DESCRIPTION OF PREFERRED EMBODIMENTS

The specific embodiments described with reference to the attached drawings are all exemplary and are intended to illustrate and interpret the present disclosure. In the description of the present disclosure, it should be understood that terms such as “upper”, “lower”, “front”, “rear”, “left”, “right”, “inside”, “outside”, “side”, as well as derivative thereof should be construed to refer to the orientation as described or as shown in the drawings under discussion. These relative terms are for convenience of description, do not require that the present disclosure be constructed or operated in a particular orientation, and shall not be construed as causing limitations to the present disclosure. The identical or similar reference numerals constantly denote the identical or similar elements or elements having the identical or similar functions in the drawings.

An embodiment of the present disclosure provides a display panel which comprises a front surface area and a back surface area. The back surface area is disposed on a back side of the front surface area through a bending area having a bending structure. In the bending area, the present disclosure can make the second electrode layer cause a less bending deformation by disposing openings respectively in the barrier layer, the first electrode layer, and the first organic layer, and disposing the second electrode layer along a bevel of the opening of the first organic layer to the substrate layer, thereby reducing a bending stress of the second electrode layer in the bending area, and reducing the risk of breaking the second electrode layer.

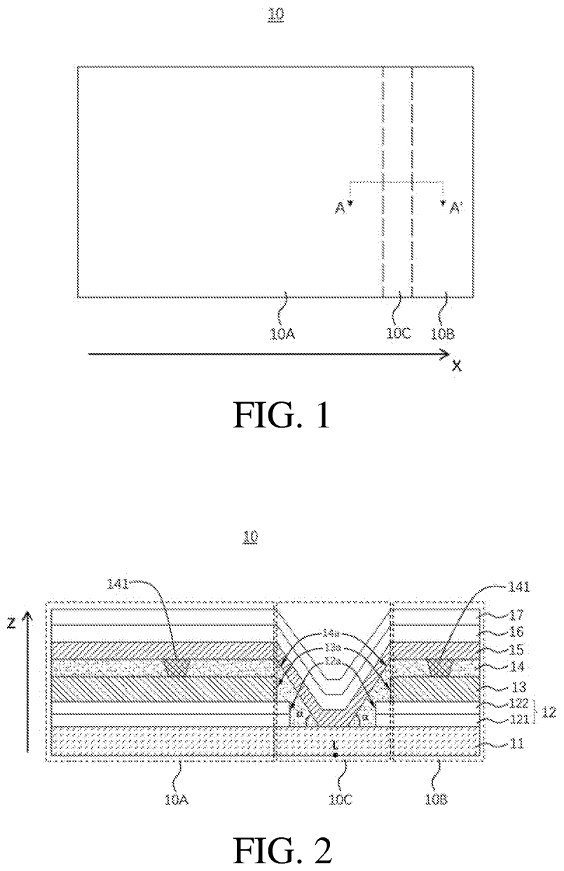

As shown in FIG. 1, FIG. 1 is a schematic structural diagram of a display panel 10 according to an embodiment of the present disclosure. The display panel 10 can be divided into a front surface area 10A, a back surface area 10B, and a bending area 100 along a width direction X of the display panel 10. Wherein, the bending area 100 has a bending structure, and the back surface area 10B is disposed on a back side of the front surface area 10A through the bending area 10C.

It should be noted that in order to clearly illustrate the structure of the display panel provided in the embodiment of the present disclosure, the display panel 10 shown in FIG. 1 is a schematic structural diagram of a display panel before the back surface area 10B is bent to the back side of the front surface area 10A. It should be understood that in the display panel 10 provided by the embodiment of the present disclosure, during all processes before performing the bending process, the front surface area 10A, the bending area 10C, and the back surface area 10B are disposed on a same side of the display panel 10. That is, at this time, the bending area 10C has not yet had a bending structure, and the back surface area 10B has not been disposed on the back side of the front surface area 10A. The display panel 10 provided in the embodiment of the present disclosure will be described below with reference to the schematic structural diagrams of the display panel before the bending process and after the bending process.

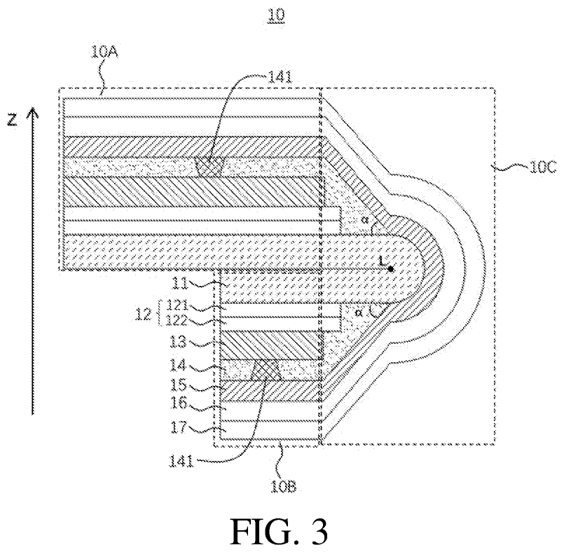

As shown in FIG. 2 and FIG. 3, wherein, FIG. 2 is a cross-sectional diagram of the display panel shown in FIG. 1 along an A-A′ direction before the bending process, and FIG. 3 is a cross-sectional diagram of the display panel shown in FIG. 1 along the A-A′ direction after the bending process.

Along a thickness direction Z of the display panel 10, the display panel 10 comprises a substrate layer 11, a barrier layer 12, a first electrode layer 13, a first organic layer 14, and a second electrode layer 15. Wherein, the thickness direction Z is perpendicular to the width direction X (referring to FIG. 1), the barrier layer 12 is disposed on the substrate layer 11, the first electrode layer 13 is disposed on a surface of the barrier layer 12 away from the substrate layer 11, the first organic layer 14 is disposed on a surface of the first electrode layer 13 away from the barrier layer 12, and the second electrode layer 15 is disposed on a surface of the first organic layer 14 away from the first electrode layer 13.

In the bending area 100, the barrier layer 12 is cut to form a first opening 12a, and the first electrode layer 13 is cut to form a second opening 13a. The barrier layer 12 forms a step structure on the first opening 12a. A width of the second opening 13a is greater than a width of the first opening 12a, which makes the first electrode layer 13 not cover endfaces of the first opening 12a, thereby preventing following risks: because the first opening 12a has steeper opening endfaces, if the first electrode layer 13 covers the endfaces of the first opening 12a, it will cause the first electrode layer 13 in the first opening 12a to generate a stress concentration and further lead to cracks.

In the bending area 10C, the first organic layer 14 is cut to form a third opening 14a, and endfaces of the third opening 14a have ramp structures. That is, the first organic layer 14 forms ramp surfaces on the endfaces of the third opening 14a, and the ramp surfaces at two ends of the third opening 14a relatively extend to the substrate layer 11. The first organic layer 14 covers the endfaces of the first opening 12a and endfaces of the second opening 13a.

In the bending area 100, the second electrode layer 15 is disposed along the endfaces of the third opening 14a, thereby preventing the risk of breaking the second electrode layer 15 in the third opening 14a caused by an excessive stress concentration.

Optionally, in the bending area 10C, an included angle α between the endfaces of the third opening 14a and the substrate layer 11 is less than 40 degrees. It should be understood that if the included angle between the endfaces of the third opening 14a and the substrate layer 11 is less, the stress concentration generated by the second electrode layer 15 on the endfaces of the third opening 14a would be less, thereby the risk of break caused by the stress concentration would also be less.

Optionally, in the bending area 10C, the two ends of the third opening 14a relatively extend to the substrate layer 11, and the two ends of the third opening 14a are not in contact with each other, thereby making a part of the second electrode layer 15 directly disposed on the substrate layer 11. It should be understood that in the bending area 100, when the bending area 100 is subjected to bending, if a distance between the second electrode layer 15 and the substrate layer 11 is less, the bending deformation generated by the second electrode layer 15 is less, and the risk of breaking the second electrode layer 15 caused by the bending deformation is also less.

Optionally, the substrate layer 11 is a flexible substrate, a material thereof may be a flexible transparent material, such as polyimide, to ensure the display panel 10 having bendability.

Optionally, the barrier layer 12 consists of an inorganic layer 121 and a third organic layer 122. The inorganic layer 121 is used to prevent outside air and moisture from entering an interior of the display panel 10. On one hand, the organic layer 122 can prevent outside air and moisture from entering the interior of the display panel 10, and on the other hand, it can prevent the risk of electrical leakage of the first electrode layer 13.

It should be noted that after the display panel 10 is subjected to the bending process, the bending area 10C is bent, which makes the back surface area 10B flipped to the back side of the front surface area 10A. At this time, in the bending area 10C, the substrate layer 11 and the second electrode layer 15 are bent around a bending center L, and at least a part of the second electrode layer 11 forms an arc structure due to bending. Because the barrier layer 12, the first electrode layer 13, and the first organic layer 14 are provided with openings in the bending area 100, there are at least following two beneficial effects: the first one is that a break of the barrier layer 12, the first electrode layer 13, and the first organic layer 14 caused by bending can be prevented, and the second one is that it reduces a distance from the second electrode layer 15 to the bending center L, which makes the second electrode layer 15 generate a less bending deformation and reduces the risk of breaking the second electrode layer 15 due to bending.

According to an embodiment of the present disclosure, the display panel 10 further comprises a second organic layer 16 and a pixel definition layer 17. The second organic layer 16 is disposed on the second electrode layer 15 and on a surface of the second electrode layer 15 away from the first organic layer 14, and the pixel definition layer 17 is disposed on the second organic layer 16 and on a surface of the second organic layer 16 away from the second electrode layer 15. The second organic layer 16 plays an insulating role. The pixel definition layer 17 comprises at least red, green, and blue sub-pixel units.

In the bending area 10C, before the bending area 10C is subjected to the bending process, the second organic layer 16 is disposed along the second electrode layer 15 and forms a concave, and the pixel definition layer 17 is disposed along the second organic layer 16 and forms a concave; after the bending area 100 is subjected to the bending process, at least a part of the second organic layer 16 and the pixel definition layer 17 forms an arc structure due to bending. It should be understood that in the bending area 100, the barrier layer 12, the first electrode layer 13, and the first organic layer 14 are provided with openings, thereby reducing a distance from the second organic layer 16 and the pixel definition layer 17 to the bending center L, thereby reducing bending deformations of the second organic layer 16 and the pixel definition layer 17, and further reducing the risk of deformation and fractures.

According to an embodiment of the present disclosure, the first organic layer 14 is provided with through holes 141 filled with a conductive material, and the first electrode layer 13 is electrically connected to the second electrode layer 15 by the conductive material in the through holes 141. It should be noted that the front surface area 10A and the back surface area 10B are provided with through holes 141, thereby making the first electrode layer 13 at two ends of the second opening 13a are respectively connected to the second electrode layer 15. The number of through holes 141 disposed in the front surface area 10A and the back surface area 10B may be plural. The first electrode layer 13 and the second electrode layer 15 may comprise a plurality of wirings and a plurality of electrodes, and at least a part of the wirings and/or electrodes in the first electrode layer 13 is connected to the wirings and/or electrodes in the second electrode layer 15 by the through holes 141.

Optionally, a flexible circuit board is disposed in the back surface area 10B, an integrated chip is disposed on the flexible circuit board, the first electrode layer 13 and the second electrode layer 15 are respectively connected to the flexible circuit board, and the integrated chip controls the display function of the display panel 10 through the first electrode layer 13 and the second electrode layer 15.

Optionally, at least the front surface area 10A is a display area and has function of displaying images, the bending area 10C and the back surface area 10B can also have the function of displaying images according to requirements of design.

In summary, the display panel 10 provided by the embodiment of the present disclosure comprises a front surface area 10A and a back surface area 10B. The back surface area 10B is disposed on a back side of the front surface area 10A through a bending area 100 having a bending structure. In the bending area 10C, the present disclosure can make the second electrode layer 15 cause a less bending deformation by disposing openings respectively in the barrier layer 12, the first electrode layer 13, and the first organic layer 14 and disposing the second electrode layer 15 along a bevel of the opening of the first organic layer 14 to the substrate layer 11, thereby reducing a bending stress of the second electrode layer 15 in the bending area, reducing the risk of breaking the second electrode layer 15, and improving quality of the display panel 10 and the yield of the process.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A display panel, comprising a display area, a back surface area, and a bending area connected to a front surface area and the back surface area;
wherein the bending area is a bending structure, and the back surface area is disposed on a back side of the front surface area through the bending area;
the display panel comprising:
a substrate layer;
a barrier layer disposed on the substrate layer;
a first electrode layer disposed on the barrier layer;
a first organic layer disposed on the first electrode layer; and
a second electrode layer disposed on the first organic layer;
wherein in the bending area, the barrier layer has a first opening, the first electrode layer has a second opening, the first organic layer has a third opening and covers an endface of the first opening and an endface of the second opening, and an endface of the third opening is a ramp structure.

2. The display panel according to claim 1, wherein in the bending area, the endface of the third opening extends to the substrate layer correspondingly.

3. The display panel according to claim 1, wherein a width of the second opening is greater than a width of the first opening.

4. The display panel according to claim 1, wherein in the bending area, an included angle between the endface of the third opening and the substrate layer is less than 40 degrees.

5. The display panel according to claim 1, wherein in the bending area, two ends of the third opening are not in contact with each other.

6. The display panel according to claim 5, wherein in the bending area, a part of the second electrode layer is disposed on the substrate layer.

7. The display panel according to claim 5, wherein in the bending area, the second electrode layer is disposed along the endface of the third opening and a surface of the substrate layer toward the barrier layer.

8. The display panel according to claim 1, wherein in the bending area, at least a part of the second electrode layer has an arc structure.

9. The display panel according to claim 1, comprising a second organic layer disposed on the second electrode layer.

10. The display panel according to claim 9, wherein in the bending area, at least a part of the second organic layer has an arc structure.

11. The display panel according to claim 9, further comprising a pixel definition layer disposed on the second organic layer.

12. The display panel according to claim 11, wherein in the bending area, at least a part of the pixel definition layer has an arc structure.

13. The display panel according to claim 11, wherein the pixel definition layer comprises red, green, and blue sub-pixel units.

14. The display panel according to claim 1, wherein the substrate layer is a flexible substrate.

15. The display panel according to claim 14, wherein the substrate layer is made of polyimide.

16. The display panel according to claim 1, wherein the first organic layer is provided with a through hole filled with a conductive material, and the first electrode layer is electrically connected to the second electrode layer by the conductive material in the through hole.

17. The display panel according to claim 16, wherein the first electrode layer and the second electrode layer comprise a plurality of wirings and a plurality of electrodes, and at least a part of the wirings and/or electrodes in the first electrode layer is electrically connected to the wirings and/or electrodes in the second electrode layer by the conductive material in the through hole.

18. The display panel according to claim 1, wherein the barrier layer consists of an inorganic layer and a third organic layer, the inorganic layer is disposed on the substrate layer, and the third organic layer is disposed on the inorganic layer.
